(19) United States
(12) Patent Application Publication
(10) Pub. No.: US 2026/0235968 A1
(43) Pub. Date: Aug. 13, 2026

(54) MICROLITHOGRAPHIC PROJECTION EXPOSURE SYSTEM

(71) Applicant: Carl Zeiss SMT GmbH, Oberkochen (DE)

(72) Inventors: Alexander VOELTER, Oberkochen (DE); Thomas WOLFSTEINER, Aalen (DE)

(21) Appl. No.: 19/637,030

(22) Filed: Apr. 2, 2026

Related U.S. Application Data
(63) Continuation of application No. PCT/EP2024/078277, filed on Oct. 8, 2024.

(30) Foreign Application Priority Data
Oct. 13, 2023 (DE) 10 2023 210 078.9

(51) Int. Cl. G03F 7/00

(52) U.S. Cl. CPC G03F 7/70891; G03F 7/70825

(57) ABSTRACT

A microlithographic projection exposure apparatus comprises an illumination system, a projection lens, and an actuator for adjusting an operating parameter of an optical element of the illumination system or an optical element projection lens. The apparatus also comprises an input interface for electrical control of the actuator. An electrical control path between the input interface and the actuator passes through a printed circuit board. The printed circuit board is in an interior of a housing equipped with a cooling channel. The printed circuit board is detachably connected to the housing such that the printed circuit board is separable from the housing without opening the cooling channel.

### CROSS-REFERENCE TO RELATED APPLICATIONS

The present application is a continuation of, and claims benefit under 35 USC 120 to, international application No. PCT/EP2024/078277, filed October 8, 2024, which claims benefit under 35 USC 119 of German Application No. 10 2023 210 078.9, filed October 13, 2023. The entire disclosure of each of these applications is incorporated by reference herein

### FIELD

The disclosure relates to a microlithographic projection exposure apparatus.

### BACKGROUND

Microlithographic projection exposure apparatuses comprising an illumination system and a projection lens are used for the production of microstructured components. The illumination system is used to direct very short-wave, deep ultraviolet radiation (DUV radiation) or extreme ultraviolet radiation (EUV radiation) to a photomask. The projection lens is used to image the photomask onto a lithography object, for example a silicon wafer, in order to transfer the mask structure onto a light-sensitive coating of the lithography object.

The projection exposure apparatus comprises several optical elements that are used to shape the beam path of the illumination system and the beam path of the projection lens. In the case of DUV radiation, the optical elements can be lens elements or DUV mirrors. In the case of EUV radiation, these may be optical elements comprising an optical surface off which the EUV radiation is reflected. Typically, the optical elements have a precisely defined shape and are precisely positioned in order that the imaging of the photomask onto the lithography object is of sufficient quality.

In order to help set the optical elements in a manner corresponding to the desired properties of the projection exposure apparatus, provision is made for actuators that can be used to influence one or more operating parameters of the optical elements. For example, the actuators can be used to influence the position, the alignment and/or the temperature of the optical elements. The actuators are typically controlled using electrical control signals.

The actuators can be controlled by way of printed circuit board modules. For effective heat dissipation, the printed circuit board modules may be equipped with liquid cooling, in which a cooling liquid is conducted through components of a printed circuit board module in order to dissipate heat from the electronic components of the printed circuit board module. However, liquid-cooled printed circuit board modules frequently can add some overheads in the case of maintenance or repair.

### SUMMARY

The disclosure seeks to present an improved microlithographic projection exposure apparatus.

In embodiments, the disclosure provides a microlithographic projection exposure apparatus comprising an illumination system and a projection lens, wherein the illumination system comprises a first set of optical elements which are designed to direct electromagnetic radiation emitted by a radiation source onto a photomask in order to illuminate the photomask with the electromagnetic radiation, and wherein the projection lens comprises a second set of optical elements in order to shape an imaging beam path used to image the photomask onto a lithography object. The microlithographic projection exposure apparatus comprises an actuator for adjusting an operating parameter of the optical element and an input interface for electrical control of the actuator. The electrical control path between the input interface and the actuator runs via a printed circuit board. The housing is equipped with a cooling channel. The printed circuit board is detachably connected to the housing such that the printed circuit board can be separated from the housing without the cooling channel being opened.

The disclosure proposes a functional separation of the printed circuit board and the liquid-cooled housing. It was found that the opening of cooling circuits in the surroundings of a microlithographic projection exposure apparatus that is a frequent source of faults during maintenance operations and repair work. Maintenance and repair work can be simplified significantly by virtue of, according to the disclosure, the printed circuit board being able to be replaced without the cooling channel being opened.

In embodiments, the microlithographic projection exposure apparatus comprises a vacuum chamber, wherein the optical elements of the illumination system and/or the optical elements of the projection lens are arranged in the vacuum chamber. The housing, within which the printed circuit board is arranged, can be arranged within the vacuum chamber. The pressure in the housing can be higher than the pressure in the vacuum chamber.

Hitherto, control in such a design was customarily effected by way of printed circuit board modules arranged outside the vacuum housing. In the case of such a design, it is pretty much unavoidable that the printed circuit board module is arranged at a distance from the controlled actuator. Transmission losses due to the distance can become increasingly undesirable as system complexity grows and the number of actuators to be controlled increases.

The losses in the transmission of electrical signals can be reduced by reducing the distance between the printed circuit board and the actuator of the optical element. To this end, the printed circuit board can be arranged in a housing that is positioned within the vacuum chamber. This can open up the possibility of operating the printed circuit board within the vacuum chamber in which the controlled optical element is arranged without the printed circuit board being exposed to the same vacuum atmosphere as the optical element. Thus, the printed circuit board can be operated under different pressure conditions than the optical element, and it is possible that any potential outgassing products from components of the printed circuit board does not penetrate as far as the optical element.

Dissipating the heat from the printed circuit board out of the housing and out of the vacuum chamber can be non-trivial if a printed circuit board is arranged within such a housing. If a pressure-tight housing were to be built around a liquid-cooled printed circuit board module, the confined space in the vicinity of an optical element would mean that replacing a defective printed circuit board would hardly be possible without dismantling the system. It is therefore proposed to equip the housing with liquid cooling while the printed circuit board is not subjected to direct liquid cooling. This can help improve the ease of maintenance because the printed circuit board can be separated from the housing without opening the cooling channel formed in the housing. Moreover, the cabling outlay can be reduced.

The cooling channel can extend in a structure of the housing. A cooling liquid used to dissipate heat from the housing can be conducted along the cooling channel during the operation of the microlithographic projection exposure apparatus. The cooling liquid can enter the structure of the housing at a lower temperature and re-emerge from the structure of the housing at a higher temperature. The cooling liquid can be guided in a circuit, wherein a heat exchanger, by way of which the cooling liquid releases heat, can be arranged between the exit from the structure of the housing and the renewed entry into the structure of the housing. The heat exchanger can be arranged outside the vacuum chamber. Between inlet and outlet, the cooling channel can be in the form of a closed cavity, within which the cooling liquid is guided. If the cooling channel were to be opened, the cooling liquid could emerge from the cavity at a different location to the intended inlet and outlet.

Between the inlet and the outlet, the cooling channel might comprise a first section, which extends within the structure of the housing, and a second section, for example in the form of a conduit, which is guided out of the structure of the housing. For example, such a conduit could extend through the interior of the housing. Between the inlet opening and the outlet opening, the cooling channel extends completely within the structure of the housing in one embodiment.

The structure of the housing may comprise or consist of a material with good thermal conductivity. In one embodiment, the structure of the housing comprises or consists of copper. Another possibility is for the housing to comprise or consist of aluminum, which is accompanied by the advantage of a lower weight. The housing may be designed such that direct contact between the cooling liquid and the copper material or aluminum material of the housing is avoided, for example by virtue of the cooling liquid being guided in a pipe, for example a steel pipe, formed in the structure of the housing.

Alternatively, the housing may also comprise or consist of steel, for example a high-alloy steel, which is accompanied by the advantage of higher mechanical strength. The lower thermal conductivity of the steel can be accepted in certain applications. Independently of the housing material, the housing may be provided with one or more heat pipes in order to improve the heat conduction. The heat pipes can be arranged within the material of the housing.

In order that heat can be dissipated from the printed circuit board by way of the liquid cooling, good heat transfer from the printed circuit board to the structure of the housing is desirable. A bearing surface, on which the printed circuit board or a printed circuit board module comprising the printed circuit board rests, may be formed in the structure of the housing. The structure of the housing may comprise a uniform structural component, within which the cooling channel extends and on which the bearing surface is formed. In the region in which the printed circuit board rests on the bearing surface, the printed circuit board can be coated with a material with good thermal conductivity. For example, a coating of copper or ENIG (electroless nickel immersion gold) can be applied as heat-conducting material in this region. This then provides a thermal path from electrical components arranged on the printed circuit board into the structure of the housing via the substrate of the printed circuit board and the heat-conducting material.

In embodiments, the printed circuit board is a constituent part of a printed circuit board module so that the printed circuit board module can be separated from the housing without the cooling channel of the housing being opened. The printed circuit board module can comprise a printed circuit board and a cooling plate. The cooling plate can be a passive cooling plate such that the heat is dissipated by heat conduction within the material of the cooling plate. The cooling plate may be thermally coupled to the printed circuit board by virtue of the printed circuit board being in physical contact with the cooling plate. The printed circuit board module can be designed such that surface portions of the printed circuit board rest on surface portions of the cooling plate. For good heat transfer, it can be desirable for the printed circuit board to be pressed against the cooling plate. In one embodiment, the printed circuit board is screwed to the cooling plate.

The printed circuit board module may comprise a cover with which the printed circuit board is covered. The printed circuit board can be arranged between the cover and the cooling plate. The cover can be screwed to the cooling plate such that the printed circuit board is pressed against the cooling plate by the cover.

Heat arising on the printed circuit board can be dissipated into the housing via the cooling plate via heat conduction. The printed circuit board module may comprise a first thermal path which extends from electrical or electronic components arranged on the printed circuit board to the cooling plate through the substrate of the printed circuit board. Surface regions of the printed circuit board resting on the cooling plate may be provided with a metallic coating in order to improve the heat transfer between the printed circuit board and the cooling plate. In general, the metallic coating should be galvanically isolated from those regions of the printed circuit board via which electrical signals are transmitted. For example, the metallic coating can be a copper coating or an ENIG (electroless nickel immersion gold) coating.

The printed circuit board module may comprise a second thermal path which extends directly from electrical or electronic components arranged on the printed circuit board to the cooling plate. The component can be thermally coupled to the printed circuit board by virtue of a gap filler in the form of a suitable thermally conductive material (thermal interface material, TIM) being arranged between the component and the cooling plate. For example, one or more components arranged on the printed circuit board can be thermally coupled to the cooling plate via a thermal paste. For example, this may relate to those components which generate particularly large amounts of heat during the operation of the microlithographic projection exposure apparatus.

Good heat transfer from the cooling plate of the printed circuit board module to the structure of the housing is promoted if there is large-area contact between the surface of the cooling plate and the bearing surface. For example, the bearing surface may extend over at least 5%, such as at least 10%, for example at least 20%, of the area of the cooling plate. In the case of a rectangular cooling plate, the area of the cooling plate is given by the product of the longer edge and the shorter edge. The cooling plate can be dimensioned such that it completely covers the printed circuit board. In an embodiment in which the printed circuit board rests directly on the structure of the housing, the specifications may relate to the area of the printed circuit board.

The housing may comprise a first bearing surface and a second bearing surface, wherein a first section of the cooling plate rests on the first bearing surface, and a second section of the cooling plate rests on the second bearing surface. The first section of the cooling plate and the second section of the cooling plate may be edge sections of the cooling plate such that the remaining surface of the cooling plate is enclosed between the first section and the second section. The printed circuit board in turn may rest with edge sections on the cooling plate.

In embodiments, the structure of the housing comprises a bearing surface which covers the surface of the cooling plate. This makes it possible for the cooling plate to be able to rest over its entire surface on the bearing surface.

For good heat transfer from the printed circuit board to the structure of the housing, it may be desirable for the printed circuit board module to be pressed against the bearing surface. For example, contact pressure can be generated by virtue of the printed circuit board module being pressed against the housing by way of a mechanical component. The housing may comprise a mating surface opposite the bearing surface. Pressure between the printed circuit board module and the bearing surface can be generated via a spreading mechanism. The spreading mechanism can be supported on the mating surface in order to press the printed circuit board module against the bearing surface. The printed circuit board module can be held between the spreading mechanism and the bearing surface.

The housing and the printed circuit board can be designed such that the printed circuit board or the printed circuit board module can be inserted into the housing in an insertion direction parallel to the surface of the bearing surface. The spreading mechanism can be configured such that the spreading mechanism can be actuated by a tool which is brought up to the spreading mechanism in the insertion direction. In order that the printed circuit board or printed circuit board module can easily be replaced in the confined spatial conditions in the surroundings of an optical element, it is desirable for the direction in which the printed circuit board or printed circuit board module is inserted to correspond to the direction from which the spreading mechanism is actuated.

If the housing has a first bearing surface and a second bearing surface and also a first mating surface and a second mating surface, then a first spreading mechanism can be used to press the printed circuit board or the printed circuit board module onto the first bearing surface, and a second spreading mechanism can be used to press the printed circuit board or the printed circuit board module onto the second bearing surface. In this context, care should be taken to ensure that jamming does not occur when the spreading mechanisms are tightened. In may therefore be expedient to tighten the first spreading mechanism and the second spreading mechanism alternately.

By virtue of the spreading mechanism exerting pressure on the printed circuit board or the printed circuit board module such that this is pressed against the bearing surface, the spreading mechanism can have the effect of reducing the air gap between the printed circuit board or cooling plate of the printed circuit board module and the bearing surface, whereby the thermal resistance can be reduced. In addition, the spreading mechanism itself may form a thermal path parallel thereto between the printed circuit board and the structure of the housing such that heat from the printed circuit board passes through the spreading mechanism into the structure of the housing. This will usually be a secondary heat path, while a majority of the heat continues to be transferred to the housing via the compressed bearing surface of the printed circuit board module.

For good heat transfer, large-area contact between the spreading mechanism and the mating surface and between the spreading mechanism and the printed circuit board or the printed circuit board module is advantageous. The spreading mechanism may comprise wedge surfaces, by which the spreading mechanism can be spread transversely to its actuation direction. The spreading mechanism can be designed such that outer surfaces of the spreading mechanism arranged in each case between two wedge surfaces are pressed against the printed circuit board or printed circuit board module and against the mating surface.

Heat can be transferred from the spreading mechanism into the structure of the housing by way of the mating surface of the housing. To further improve the heat transfer, the spreading mechanism may comprise one or more outer surfaces which rest against the structure of the housing in a direction transverse to the spreading direction.

Electrical contacts which are designed to establish electrical contact to the printed circuit board can be formed in the housing. These can be plug-in contacts. The electrical contacts can be designed such that they automatically make contact when the printed circuit board or the printed circuit board module is correctly inserted into the housing. The electrical contacts can be formed on a connection board which is arranged in the housing.

An output interface, by which a voltage supply and/or electrical control signals for controlling the actuators of the microlithographic projection exposure apparatus are transmitted, can be formed on the housing. The output interface can be formed on the same connection board to which the printed circuit board is also connected. Control signals can be conducted directly from the output interface to the actuators. It is also possible for a further control level, which receives control information from the output interface and processes the control information in order to generate control commands for the actuators, to be interposed between the output interface and the actuators. The output interface can also be designed to transmit sensor data obtained within the microlithographic projection exposure apparatus into the housing and to the printed circuit board.

The printed circuit board may have input contacts that are in electrical contact with the input interface of the housing. The printed circuit board may have output contacts that are in electrical contact with the output interface. The number of electrical contacts on the output interface may be greater than, such as greater than by at least a factor of 2, for example greater by than at least a factor of 5, the number of electrical contacts on the input interface. This opens up the possibility of controlling a larger number of actuators of the microlithographic projection exposure apparatus.

In the case of the microlithographic projection exposure apparatus according to the disclosure, the housing can be arranged in the interior of the vacuum chamber, in which the optical element is also arranged. A high vacuum may be present in the vacuum chamber during the operation of the microlithographic projection exposure apparatus. For example, the pressure in the vacuum chamber can be between 10⁻⁶ mbar and 10⁻⁹ mbar, such as between 10⁻⁷ and 10⁻⁸ mbar. Electronic components are often not designed to be operated at such a low pressure, which is why a pressure that is higher than the pressure in the vacuum chamber may be present in the housing in which the printed circuit board is arranged. The pressure in the housing can be greater than 10⁻² mbar, such as greater than 10⁻¹ mbar. In embodiments, atmospheric pressure is present in the housing.

In order to be able to maintain the pressure difference, a hermetic separation between the interior of the housing and the pressure in the vacuum chamber is advantageous. In embodiments, the housing itself is designed such that the interior of the housing is hermetically separated from the vacuum conditions in the vacuum chamber. It is also possible for a hermetically sealed outer housing to be arranged within the vacuum chamber and for the housing with the printed circuit board to be arranged in the interior of the outer housing. In that case, there can be free pressure exchange between the interior of the outer housing and the interior of the housing with the printed circuit board.

In the case of a printed circuit board fault, the printed circuit board or the printed circuit board module can be pulled out of the housing without the cooling channel of the housing being opened. The housing can be designed such that electrical contact between the printed circuit board and the connection board is broken and the printed circuit board or the printed circuit board module is pulled out at the same time. The vacuum chamber, the housing and optionally the outer housing can be designed such that they can be opened for the removal of the printed circuit board or the printed circuit board module in order to allow access to the printed circuit board or printed circuit board module from outside the vacuum chamber.

The housing can be designed such that the connection board remains in its position when the printed circuit board or the printed circuit board module is pulled out of the housing. In embodiments, the housing is designed such that the printed circuit board can be detached from the housing together with the connection board without the cooling channel being opened. For this purpose, the housing may be equipped with a plug-in unit which carries both the connection board and the printed circuit board. In a variant, there is a choice of removing the plug-in unit from the housing or removing the printed circuit board from the plug-in unit.

It is also possible for the housing to be designed such that the connection board cannot be removed from the housing without the cooling channel of the housing being opened. In order to allow a removal of the connection board, the housing may comprise a first housing part and a second housing part which can be separated from each other at a separation point. Following the separation of the first housing part from the second housing part, the connection board can be removed from the housing. The cooling channel can extend over the separation point such that a first section of the cooling channel is formed in the first housing part, and a second section of the cooling channel is formed in the second housing part. Thus, the cooling channel is opened when the first housing part is separated from the second housing part.

The inlet of the cooling channel into the housing and the outlet of the cooling channel from the housing can be arranged in the first housing part. The input interface, the printed circuit board and the output interface may be arranged in the second housing part. In this way, the second housing part with the electrical components can be detached from the first housing part in order to render the electrical components accessible for maintenance. This is possible without opening the connections of the cooling channel arranged in the first housing part.

Such maintenance of electrical components may become desirable if faults occur on electrical components other than the printed circuit boards. According to the disclosure, the printed circuit boards, which are afflicted by a higher susceptibility to faults, can be replaced without the cooling channel being opened. The housing may comprise a housing cover which allows such access to the printed circuit board.

The optical element of the microlithographic projection exposure apparatus can be an EUV mirror, i.e. a highly reflective mirror for electromagnetic radiation with wavelengths between 5 nm and 30 nm, for example 13.5 nm. The EUV mirror can comprise a mirror body, on which a continuous optical surface is formed. This can be an EUV mirror of a projection lens of the microlithographic production exposure apparatus. The actuators can be designed to adjust the alignment of the mirror body relative to a frame structure and/or an operating parameter associated with the thermal state of the EUV mirror.

It is also possible for the EUV mirror to be an EUV mirror of the illumination system of the microlithographic projection exposure apparatus. In one embodiment, the EUV mirror is a facet mirror having a multiplicity of small mirror elements. For example, the EUV mirror can be a MEMS mirror module. The MEMS mirror module can comprise a multiplicity of small mirror elements, which are each mounted so as to be individually movable relative to a common base. For each mirror element, an actuator can be provided and can allow the mirror element to be adjusted along a predetermined degree of freedom. Sensors that can be used to establish the position of the mirror element vis-à-vis the carrier base can be provided. The sensors can be used to monitor the alignment of the mirrors.

There can be more than 10,000, such as more than 50,000, for example more than 100,000 mirror elements in the MEMS mirror module, which can involve a corresponding number of actuators. The features of the disclosure can be particularly useful given such a high number of actuators.

In embodiments, the optical element is a constituent part of a microlithographic projection exposure apparatus operated with DUV radiation. DUV radiation refers for example to electromagnetic radiation with wavelengths between 150 nm and 400 nm. The optical element can be a constituent part of a DUV projection lens, for example a DUV lens element or a DUV mirror. The optical element can be a constituent part of a DUV illumination system, for example a DUV lens element or a DUV mirror. The DUV projection exposure apparatus can be designed such that the optical element is operated at atmospheric pressure. The pressure within the housing in which the printed circuit board is arranged may match the pressure to which the optical element is exposed. The optical element can be a lens element of a DUV projection lens. The optical element can be a DUV mirror of a DUV projection lens.

The disclosure also relates to a system comprising a vacuum chamber and a printed circuit board. The printed circuit board is arranged in an interior of a housing positioned within the vacuum chamber, wherein the housing is equipped with a cooling channel. In a first state of the system, vacuum pressure is present in the vacuum chamber, and the pressure in the housing is greater than the pressure in the vacuum chamber. In a second state of the system, the pressure in the interior of the housing corresponds to the pressure in the vacuum chamber such that the printed circuit board, which is detachably connected to the housing, can be separated from the housing without the cooling channel being opened. In such a system, the features of the disclosure can be used in order to control other components arranged in a vacuum chamber than the optical element. The disclosure encompasses developments of the system with features that are described in the context of the mirror system according to the disclosure.

### BRIEF DESCRIPTION OF THE DRAWINGS

The disclosure is described by way of example below on the basis of certain embodiments and with reference to the accompanying drawings, in which:

FIG. 1: shows an embodiment of a projection exposure apparatus according to the disclosure;

FIG. 2: shows an embodiment of a microlithographic projection exposure apparatus according to the disclosure;

FIG. 3: shows a schematic illustration of the housing of the microlithographic projection exposure apparatus from FIG. 2;

FIG. 4: shows an aspect of the housing from FIG. 3;

FIG. 5: shows another aspect of the housing from FIG. 3;

FIG. 6: shows a detail of the housing from FIG. 5 in an enlarged illustration;

FIG. 7: shows the view in accordance with FIG. 6 in an alternative embodiment of the disclosure;

FIG. 8: shows the spreading mechanism from FIG. 6 in a schematic illustration;

FIG. 9: shows an embodiment of a housing according to the disclosure;

FIG. 10: shows a schematic illustration of an embodiment of a microlithographic projection exposure apparatus according to the disclosure;

FIG. 11: shows a detail of the microlithographic projection exposure apparatus from FIG. 10 in an enlarged illustration; and

FIG. 12: shows a printed circuit board module of a microlithographic projection exposure apparatus according to the disclosure.

### DETAILED DESCRIPTION

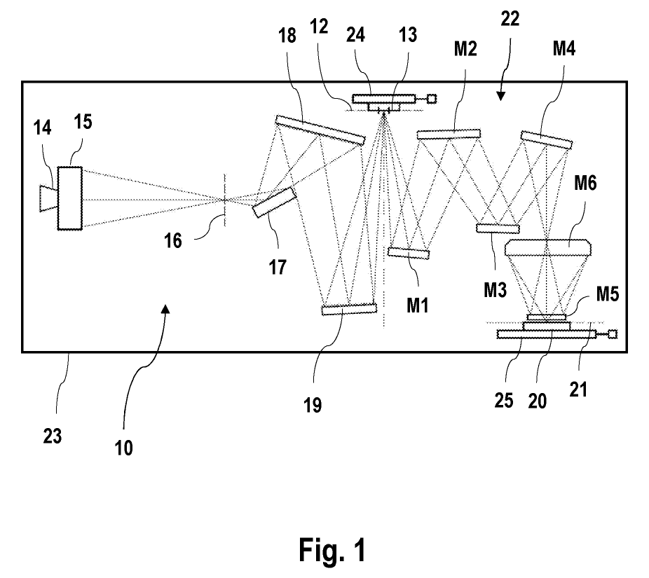

FIG. 1 schematically illustrates a microlithographic EUV projection exposure apparatus. The projection exposure apparatus comprises an exposure beam source 14, an illumination system 10 and a projection lens 22, which are operated jointly in a vacuum chamber 23.

The exposure beam source 14 generates electromagnetic radiation in the EUV range, i.e. at a wavelength of between 5 nm and 30 nm for example. The exposure radiation emanating from the exposure beam source 14 is focused into an intermediate focal plane 16 by way of a collector 15. Exposure radiation passing across the intermediate focal plane 16 is guided into an object plane 12 by the illumination system 10, with the result that an object field in the object plane 12 is illuminated with uniform radiation intensity.

The illumination system 10 comprises a deflection mirror 17 used to deflect the exposure radiation to a first facet mirror 18. A second facet mirror 19 is disposed downstream of the first facet mirror 18. The second facet mirror 19 is used to image the facets of the first facet mirror 18 into the object plane 12.

A photomask 13 is arranged in the object plane 12 and is imaged into an image plane 21 by way of a plurality of mirrors M1-M6 of the projection lens 22. A structure formed on the photomask 13 is transferred to a radiation-sensitive layer of a wafer 20 arranged in the image plane 21. The photomask 13 is suspended from a first scanning device 24, and the wafer 20 is at rest on a second scanning device 25 such that the wafer 20 can be exposed in a scanning procedure during which the photomask 13 and the wafer 20 are moved synchronously with one another.

The various mirrors of the projection exposure apparatus at which the illumination radiation is reflected are configured as EUV mirrors. The EUV mirrors are provided with highly reflective coatings. Multilayer coatings can be involved, for example multilayer coatings having alternating layers of molybdenum and silicon.

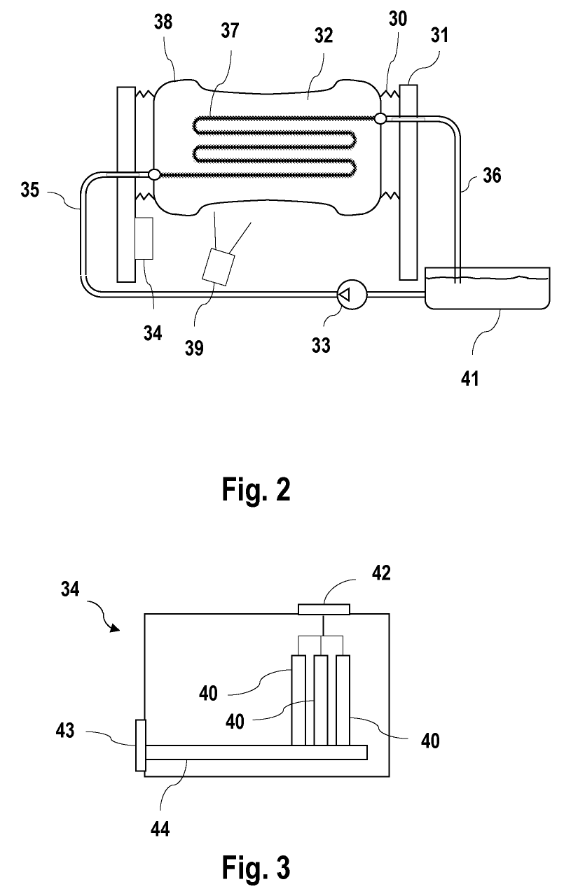

One or more of the EUV mirrors M1-M6 can be constituent parts of an EUV mirror system as illustrated schematically in FIG. 2. A mirror body 38 of a mirror M1-M6 is held on a frame structure 31 via adjustment mechanisms 30. The adjustment mechanisms 30 can be used to alter the position of the mirror body 38 relative to the frame structure 31 for the purpose of orienting and positioning the mirror body 38. An optical surface 32 off which EUV radiation is reflected is formed on the mirror body 38.

A cooling channel 37, which extends through the mirror body 38 along a serpentine path, is formed in the interior of the mirror body 38. The cooling channel 37 is part of a cooling system in which a coolant is conveyed along a closed cooling circuit via a pump 33. The cooling circuit extends from the pump 33 through a feed line 35 to the cooling channel 37 and, through a return line 36, back to a supply container 41, from where the coolant is aspirated by the pump 33. The feed line 35 and the return line 36 have sufficient flexibility so that adjustment and alignment of the mirrors is not impeded. The coolant takes up heat arising due to the absorbed EUV radiation and removes it from the mirror body 38.

A heating device 39 is arranged and aligned such that infrared radiation emitted by the heating device 39 can be directed to the optical surface 32 of the EUV mirror. Using the heating apparatus 39, it is possible to supply heat to the mirror body 38 in order to keep the optical surface 32 at a target temperature during the operation of the projection exposure apparatus.

The adjustment mechanisms 30, the pump 33 of the cooling circuit and the heating device 39 each form actuators of the EUV mirror system, and the actuators can be used to adjust operating parameters of the EUV mirror. The EUV mirror system comprises a controller which controls the actuators of the EUV mirror system on the basis of various input variables. The controller includes a housing 34, which is attached to the frame structure 31 of the EUV mirror in the exemplary embodiment shown.

In this exemplary embodiment, the housing 34 is pressure-tight and forms a hermetic separation between the interior and exterior of the housing 34. This allows the components in the interior of the housing 34 to be operated at a pressure which deviates from the vacuum conditions to which the EUV mirrors M1-M6 are exposed. For example, a pressure approximately corresponding to atmospheric pressure may be present in the interior of the housing 34.

According to the schematic illustration in FIG. 3, the housing 34 is provided with an input interface 42 and an output interface 43. In the exemplary embodiment, the EUV mirror system is supplied with electricity via the input interface 42, and control signals such as sensor data and other control information relevant to the operation of the EUV mirror system are transmitted.

A connection board 44 connected to the output interface 43 is arranged in the interior of the housing 34. The connection board 44 is provided with a plurality of plug-in locations, into which printed circuit board modules 40 are plugged. The printed circuit board modules 40 are electrically coupled to the input interface 42. Coupling can be effected via a vacuum-suitable cable bushing or cable connection.

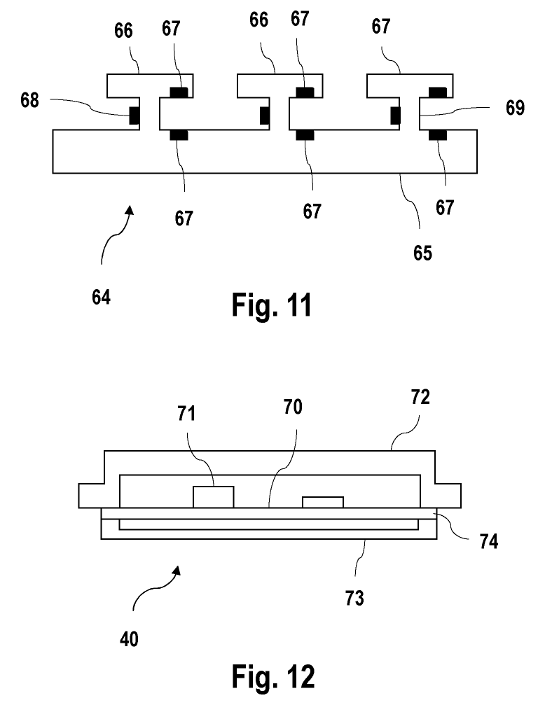

According to FIG. 12, each printed circuit board module 40 comprises a printed circuit board 70 with electronic components 71. The printed circuit board module 40 also comprises a cooling plate 72 which extends parallel to the printed circuit board 70 and covers certain parts of the printed circuit board 70. With its edge region, the printed circuit board 70 rests on a projection of the cooling plate 72 such that the electronic components 71 are enclosed between the printed circuit board 70 and the cooling plate 72. The opposite side of the printed circuit board 70 is covered by a cover 73 which is screwed to the cooling plate 72. The printed circuit board 70 arranged between the cover 73 and the cooling plate 72 is pressed against the cooling plate 72 by the screw connection.

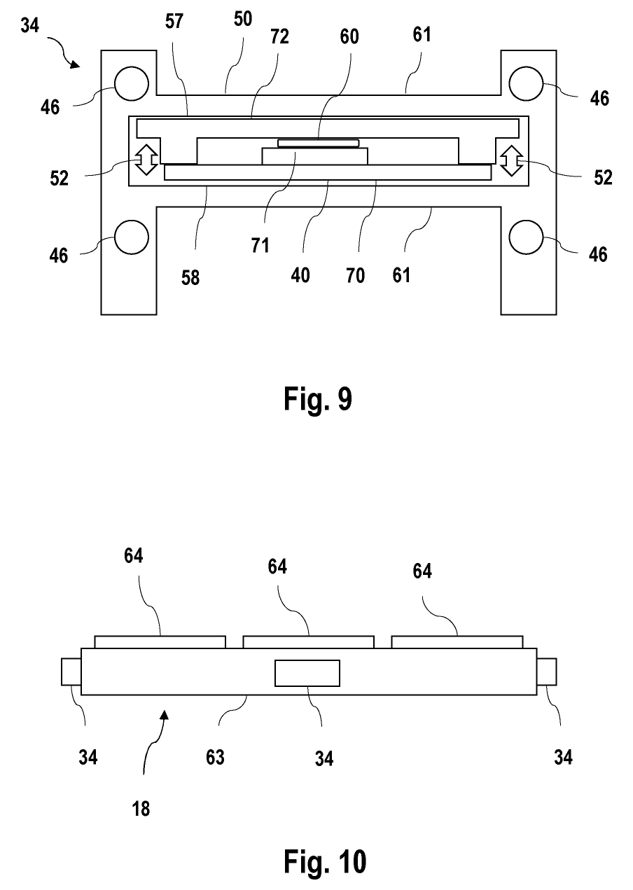

Heat generated in the electronic components 71 spreads into the substrate of the printed circuit board 70 by heat conduction and is transferred into the cooling plate 72 via the edge region 74 of the printed circuit board 70. The edge region 74 of the printed circuit board 70 is provided with a metallic coating such that there is good thermal conductivity. In the case of components which generate large amounts of heat, it is advisable to attach the components to the cooling plate, as may be achieved by the use of gap pads/gap fillers and the design of the cooling plate with a bearing surface; see FIG. 9.

There are printed circuit board modules 40 whose printed circuit boards 40 are designed as DC/DC converters, by way of which the EUV mirror system is supplied with voltage. Other printed circuit board modules 40 carry FPGAs (field programmable gate arrays), which assume control functions for the EUV mirror system. In this exemplary embodiment, each printed circuit board module 40 has input contacts which are electrically connected to the input interface 42 and output contacts which are coupled via the connection board 44 to the output interface 43.

The actuators of the EUV mirror system can be controlled directly from the output interface 43. It is also possible for a further control level, which processes control commands received from the output interface 43 in order to control the actuators, to also be arranged between the output interface 43 and the actuators. The number of electrical contacts of the output interface 43 can be substantially higher than the number of electrical contacts of the input interface 42. All computing operations within the housing 34 are performed by printed circuit boards 70 of the printed circuit board modules 40. The connection board 44 only serves to transmit signals to the output interface 43.

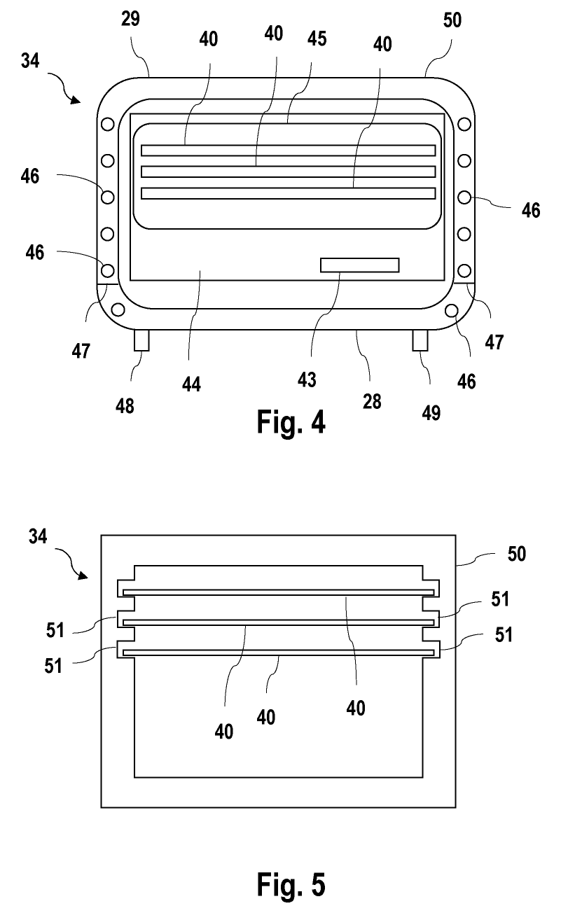

According to the further schematic illustration in FIG. 4, the housing 34 is provided with an inlet 48 and an outlet 49 of a liquid cooling system. A cooling channel 46, which extends over a large area of the housing 34 along a serpentine path, is formed in the interior of the structure 50 of the housing 34. The cooling channel 46 forms a closed path between the inlet 48 and the outlet 49. Cooling liquid flowing in through the inlet 48 moves along a predetermined path as far as the outlet 49 and has no further possibility of leaving the cooling channel 46.

The housing 34 has a separation point 47 at which an upper part 29 of the housing 34 can be separated from a lower part 28 of the housing 34. The liquid cooling system is also opened when the housing 34 is opened at the separation point 47, with the result that liquid situated in the cooling channel 46 can leak out in the region of the separation point 47. The inlet 48 of the cooling channel 46 into the housing 34 and the outlet 49 of the cooling channel 46 from the housing 34 are connected to the lower part 28 of the housing 34 such that the cooling circuit need not be opened at this point when the upper part 29 of the housing 34 is lifted off the lower part 28 of the housing 34. The printed circuit board modules 40 and the connection board 44 as well as the input interface 42 and the output interface 43 are connected to the upper part 29 of the housing 34 such that these become accessible for maintenance when the upper part 29 is lifted off.

Such a maintenance step becomes desirable, for example, if the connection board 44 or the electrical lines in the vicinity of the connection board 44 develop a fault. Such faults do not have a high probability because the connection board 44 and the electrical lines are simple electrical components. The more complex electronics with a higher susceptibility to faults are accommodated completely in the printed circuit board modules 40.

In order to be able to eliminate faults in the printed circuit board modules 40, the housing 34 is provided with a housing cover 45, which can be lifted off without the cooling channel 46 being opened. In a further schematic illustration, FIG. 5 indicates the view that emerges after the housing cover 45 has been opened. The structure 50 of the housing 34 comprises or consisting of solid copper is provided with grooves 51 which extend into the depth of the housing 34 and which define an insertion direction for the printed circuit board modules 40. The grooves 51 form a type of rail along which a printed circuit board 40 can be inserted into the housing 34. Electrical contacts of the connection board 44, which automatically make contact when the printed circuit board 40 has been correctly inserted along two grooves 51, are formed in a rear section of the housing 34.

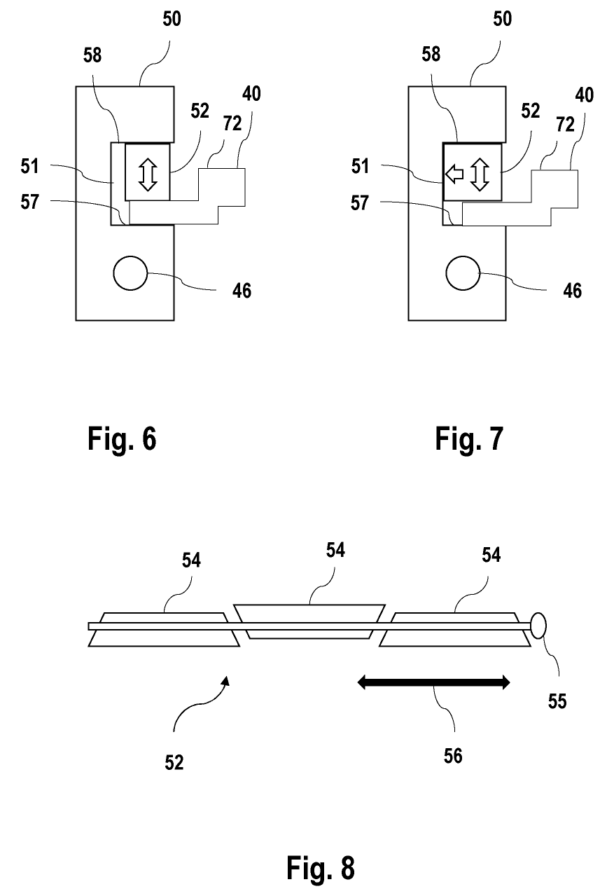

In accordance with the enlarged illustration in FIG. 6, one surface of the groove 51 forms a bearing surface 57 on which a peripheral section of the printed circuit board module 40 rests. A spreading mechanism 52 is arranged between an opposite surface of the printed circuit board module 40 and a mating surface 58 of the groove 51. The spreading mechanism 52 is spread in the direction of the arrow in order to press the printed circuit board 40 against the bearing surface 57. In accordance with FIG. 8, the spreading mechanism 52 comprises multiple blocks 54, which bear against one another by way of wedge surfaces. The blocks 54 can be tensioned against one another in the longitudinal direction 56 via a tensioning device 55 and are thereby spread apart in a direction transverse to the longitudinal direction 56. The large surfaces of the blocks 54 then press against either the mating surface 58 or the printed circuit board module 40. The pressure is transferred to the bearing surface 57 via the printed circuit board module 40.

This yields two parallel thermal paths, by way of which heat arising in electronic components 71 of the printed circuit boards 70 during operation of the EUV mirror system can be dissipated. A first thermal path extends from the electronic component 71 via the substrate of the printed circuit board 70 and the edge region of the cooling plate 72 to the structure 50 of the housing, where the heat can be dissipated via the cooling channel 46. A second thermal path extends from the electronic component 71 through the substrate of the printed circuit board 70, the edge region of the cooling plate 72 and the spreading mechanism 52 into the structure 50 of the housing 34.

FIG. 7 shows an alternative embodiment of a spreading mechanism 52 which is additionally spread in a direction transverse thereto. This yields a further surface by which the spreading mechanism 52 rests against the structure 50 of the housing 34, and so the heat transfer from the printed circuit board module 40 to the housing 34 is further improved.

In the alternative embodiment of a housing 34 in FIG. 9, the structure 50 of the housing 34 comprises planar regions 61 which extend over the surface of the printed circuit board module 40 above the printed circuit board module 40 and below the printed circuit board module 40. The planar regions 61 are provided with cooling channels 46 in a manner similar to other regions of the structure 50 of the housing 34. The schematically indicated spreading mechanisms 52 are supported between a mating surface 58 and the printed circuit board module 40 in order to press the printed circuit board module 40 against the surface of the upper planar region 61 over an extensive area. This can improve the cooling effect because the available area through which heat can transfer from the cooling plate 72 of the printed circuit board module 40 into the structure 50 of the housing 34 is increased.

An electronic component 71 which emits particularly large amounts of heat during the operation of the EUV mirror system is illustrated on the upper side of the printed circuit board 40. The electronic component 71 is thermally coupled to the cooling plate 72 of the printed circuit board module 40 there above via a thermal paste 60.

FIG. 10 illustrates a schematic illustration of the first facet mirror 18 of the illumination system 10 of the microlithographic projection exposure apparatus, in which the first facet mirror 18 is in the form of a MEMS mirror module. The MEMS mirror module comprises a frame structure 63 which carries a plurality of multi-mirror units 64. Multiple housings 34 of the type described are attached to the frame structure 63.

The MEMS mirror module may comprise a large number of multi-mirror units 64, for example several hundred such units. Each multi-mirror unit 64 may in turn comprise a large number of small mirror elements, and so the MEMS mirror module can comprise tens of thousands of mirror elements overall.

FIG. 11 illustrates a section of a multi-mirror unit 64 with three mirror elements 66. Each mirror element 67 is connected to a base 65 of the multi-mirror unit 64 via a flexure 69. Actuators 67 can be used to change the alignment of the mirror elements 66 relative to the base 65. Each mirror element 66 is also assigned a sensor 68, which is used to ascertain the current alignment of the mirror element 66.

Each of the housings 34 is responsible for controlling a portion of the mirror elements 67 of the MEMS facet mirror. The controller may be organized in such a way that each of the multi-mirror units 64 comprises a control unit for controlling the individual mirror elements 66 and that the control units of the multi-mirror units 64 are controlled from the housings 34. In this case, the housings 34 may jointly form the complete interface to the outside such that the entire electrical power for actuating the actuators 67 and all of the relevant control information can be fed into the system of the MEMS mirror module by way of the housings 34.

What is claimed is:

1. A microlithographic projection exposure apparatus having an object field in an object plane and an image field in an image plane, the projection exposure apparatus comprising:
an illumination system comprising a first set of optical elements configured to direct electromagnetic radiation to the object field so that, when a first object is present in the object field, the first object is illuminated with the electromagnetic radiation;
a projection lens comprising a second set of optical elements configured so that, when the first object is in the object field and a second object is in the image field, the first object is imaged onto the second object;
an actuator configured to adjust an operating parameter of an optical element selected from the group consisting of the first set of optical elements and the second set of optical elements;
an input interface configured to electrically control the actuator;
a housing having a structure with an interior;
a printed circuit board module detachably connected to the housing so that the printed circuit board module is separable from the housing, the printed circuit board module comprising:
a printed circuit board in the interior of the housing, the printed circuit board being in an electrical control path between the input interface and the actuator; and
a cooling plate thermally coupled to the printed circuit board, the cooling plate supported by a bearing surface of the structure of the housing.

2. The microlithographic projection exposure apparatus of claim 1, further comprising a vacuum chamber having an interior, wherein:
the first set of optical elements and/or the second set of optical elements are in the interior of the vacuum chamber;
the housing is in the interior of the vacuum chamber; and
a pressure in the housing is greater than a pressure in the vacuum chamber.

3. The microlithographic projection exposure apparatus of claim 2, wherein the structure of the housing hermetically separates the interior of the housing from the interior of the vacuum chamber.

4. The microlithographic projection exposure apparatus of claim 1, wherein the housing comprises a cooling channel.

5. The microlithographic projection exposure apparatus of claim 4, wherein the printed circuit board module is separable from the housing without opening the cooling channel.

6. The microlithographic projection exposure apparatus of claim 5, wherein the cooling channel is in the structure of the housing.

7. The microlithographic projection exposure apparatus of claim 4, wherein the cooling channel is in the structure of the housing.

8. The microlithographic projection exposure apparatus of claim 4, wherein the housing comprises a first housing part and a second housing part which are separable from each other at a separation point, and the cooling channel is disposed over the separation point.

9. The microlithographic projection exposure apparatus of claim 1, wherein the printed circuit board comprises a heat-conducting material in a region of the printed circuit board that is supported by the cooling plate.

10. The microlithographic projection exposure apparatus of claim 1, further comprising a spreading mechanism supported by a mating surface of the housing, wherein the mating surface is opposite the bearing surface.

11. The microlithographic projection exposure apparatus of claim 1, wherein the spreading mechanism is configured to press the cooling plate against the bearing surface.

12. The microlithographic projection exposure apparatus of claim 11, wherein the spreading mechanism is configured to be spread transversely to an actuation direction of the spreading mechanism.

13. The microlithographic projection exposure apparatus of claim 12, wherein the spreading mechanism provides a thermal path between the cooling plate and the structure of the housing so that heat from the printed circuit board module passes through the spreading mechanism into the structure of the housing.

14. The microlithographic projection exposure apparatus of claim 11, wherein the spreading mechanism provides a thermal path between the cooling plate and the structure of the housing so that heat from the printed circuit board module passes through the spreading mechanism into the structure of the housing

15. The microlithographic projection exposure apparatus of claim 1, wherein the second set of optical elements comprises EUV mirrors.

16. The microlithographic projection exposure apparatus of claim 15, wherein the actuator is configured to adjust an operating parameter an EUV mirror of the second set of optical elements.

17. The microlithographic projection exposure apparatus of claim 1, the optical element that is adjustable by the actuator comprises a MEMS mirror module.

18. The microlithographic projection exposure apparatus of claim 1, wherein the projection lens is an EUV projection lens.

19. The microlithographic projection exposure apparatus of claim 1, wherein the second set of optical elements comprises DUV mirrors and/or DUV lenses, and the actuator is configured to adjust an operating parameter a DUV mirror or a DUV lens of the second set of optical elements.

20. A method, comprising:
providing a microlithographic projection exposure apparatus according to claim 1;
using the illumination system to illuminate a photomask in the object plane of the microlithographic projection exposure apparatus; and
using the projection lens to image the illuminated photomask onto a light-sensitive material in the image plane of the microlithographic projection exposure apparatus.
